(19) United States
(12) Patent Application Publication
(10) Pub. No.: US 2006/0011933 A1
(43) Pub. Date: Jan. 19, 2006

(54) Optoelectronic device manufacturing

(75) Inventors: Walter Riess, Thalwil (CH); Heike E. Riel, Rueschlikon (CH); Siegfried F. Karg, Adliswil (CH)

Correspondence Address: LOUIS PAUL HERZBERG, 3 CLOVERDALE LANE, MONSEY, NY, 10952, US

(73) Assignee: International Business Machines Corporation, Armonk, NY (US)

(21) Appl. No.: 11/182,437

(22) Filed: Jul. 15, 2005

(30) Foreign Application Priority Data
Jul. 16, 2004 (EP) 04405455.9

(51) Int. Cl. H01L 33/00

(52) U.S. Cl. 257/98; 257/80; 257/85; 257/94; 257/103

(57) ABSTRACT

Provides optoelectronic devices and methods for manufacturing an optoelectronic devices. Optoelectronic devices including a capping layer for improving out-coupling and optical fine-tuning of emission characteristics. The present invention is particularly advantageous for top-emitting devices and for organic light emitting devices. An example optoelectronic device includes an optoelectronic member for emitting light, a light emitting surface and a capping layer on the light emitting surface. The capping layer includes a mixture of a first material having a first refractive index and a second material having a second refractive index.

### FIELD OF THE INVENTION

The present invention refers to an optoelectronic device and particularly to an optoelectronic device comprising a capping layer for improving out-coupling and optical fine-tuning of emission characteristics. The present invention is particularly advantageous for top-emitting devices and for organic light emitting devices.

### BACKGROUND OF THE INVENTION

In the course of the last few years, organic light emitting materials have increasingly been used for optoelectronic devices, in particular for display devices. First applications have been small display devices for cellular telephones and other mobile units, future applications include computer displays and TV sets. These display devices comprise a light emitting surface through which the light from the organic material is to be emitted. The light emitting surface is covered by a dielectric capping layer. The dielectric capping layer is crucial for improving out-coupling and optical fine-tuning of emission characteristics, in particular in top-emitting devices, i.e. devices emitting not through the bottom substrate.

For an improved out-coupling of light from the optoelectronic device, light reflection from the emitting surface can be suppressed by the presence of the capping layer. This is a question of optical path length which depends on the thickness and the refractive index of the capping layer and on the refractive indices of adjacent materials. With colour displays out-coupling is an even more complex topic. The optimum thickness of the capping layer varies with the desired wavelength of the emitted light.

Optical fine-tuning of emission characteristics primarily means fine-tuning of the spectral properties and the solid angle of emission. A conventional solution for the above-referenced problems is a capping layer made from wide-band-gap, high-refractive-index materials. However, these materials are frequently not compatible with the organic light emitting device itself. Many high-index materials are oxides that tend to react chemically with the low work function cathode materials used for OLEDs. Furthermore, most of the deposition methods used for high refractive index materials are costly and frequently incompatible with OLED preparation.

### SUMMARY OF THE INVENTION

Therefore, it is a general aspect of the present invention to provide a capping layer, an optoelectronic device with a capping layer, the optical properties of which are easily adjusted, and methods for manufacturing the optoelectronic device and for defining the refractive index of a capping layer.

In accordance with an aspect of the present invention there is provided an optoelectronic device comprising an optoelectronic member for emitting light, a light-emitting surface, and a capping layer on the light-emitting surface. The capping layer comprises a mixture of a first material having a first refractive index and a second material having a second refractive index.

In accordance with another aspect of the present invention there is provided a capping layer disposed on an electrode. The capping layer comprises a mixture of a first material having a first refractive index and a second material having a second refractive index. The refractive index of the capping layer depends on the volume ratio of the first and second material. In accordance with a further aspect of the present invention there is provided a display device comprising the optoelectronic device with the capping layer as described above.

In accordance with yet a further aspect of the present invention there is provided a method for manufacturing an optoelectronic device.

In accordance with yet another aspect of the present invention there is provided a method for defining the refractive index of a capping layer of an optoelectronic device.

### BRIEF DESCRIPTION OF THE DRAWINGS

These and other objects and features of the present invention will become clear from the following description taken in conjunction with the accompanying drawings, in which:

FIG. 1 is a schematic sectional view of an optoelectronic device according to the present invention;

FIG. 2 is a schematic flow chart of a method according to an embodiment of the present invention; and

FIG. 3 is a schematic flow chart of a method according to another embodiment of the present invention.

### DESCRIPTION OF THE INVENTION

The present invention provides capping layers, an optoelectronic devices with a capping layer. The optical properties of these are easily adjusted. Also provided are methods for manufacturing the optoelectronic devices and for defining the refractive index of a capping layer.

In accordance with the present invention there is provided an embodiment of an optoelectronic device comprising an optoelectronic member for emitting light, a light-emitting surface, and a capping layer on the light-emitting surface. The capping layer comprises a mixture of a first material having a first refractive index and a second material having a second refractive index.

In accordance with the present invention there is further provided an embodiment of a capping layer disposed on an electrode. The capping layer comprises a mixture of a first material having a first refractive index and a second material having a second refractive index. The refractive index of the capping layer depends on the volume ratio of the first and second material.

In accordance with the present invention there is further provided an embodiment of a display device comprising the optoelectronic device with the capping layer described above.

In accordance with the present invention there is further provided an embodiment of a method for manufacturing an optoelectronic device. The method comprises the steps of (i) producing an optoelectronic member for generating photons of a predefined wavelength, (ii) producing a light emitting surface on the optoelectronic member, and (iii) producing a capping layer on the light emitting surface, wherein the capping layer comprises a mixture of a first material having a first refractive index and a second material having a second refractive index.

In accordance with the present invention there is further provided an embodiment of a method for defining the refractive index of a capping layer of an optoelectronic device. This method comprises the steps of (a) providing a first material having a first refractive index and a second material having a second refractive index, (b) determining a volume ratio of the first material and the second material such that a mixture of the first material and the second material with the determined volume ratio has a predetermined refractive index, and (c) producing the capping layer from the mixture of the first material and the second material at the determined volume ratio.

According to an advantageous embodiment, the mixture comprises granules of the second material which are preferably smaller than the wavelengths of light which can be emitted by the optoelectronic member. The second refractive index of the second material is preferably higher than the first refractive index. The first material may be a desiccant, a polymer, a liquid crystal system, a wax etc. whereas the second material is preferably titanium oxide. The mixture may comprise granules from a third material having a third refractive index, wherein the granules of the third material are preferably smaller than the wavelength of the photons. It is advantageous that the mixture and the refractive index of the mixture vary within the capping layer.

According to another advantageous embodiment, the optoelectronic member, that is also referred to as photon generating member, comprises an anode, a cathode and a light emitting material between the anode and the cathode. The light emitting material is preferably an organic material or a stack of organic materials. Preferably, the light emitting surface is a surface of the anode or the cathode. In particular, the light emitting surface is a surface of the cathode, the material of the cathode comprises a low work function material and the second material is an oxide or sulfide. Preferably, the capping layer is covered or encapsulated by a transparent material. Preferably, the capping layer is produced in a step of spraying the mixture on the light emitting surface. Alternatively, the first material is produced in a chemical reaction from a raw material during deposition of the raw material on the light emitting surface.

The basic idea underlying the present invention is to provide an optoelectronic member with a capping layer made of a mixture of two materials having a first refractive index and a second refractive index. Optical properties of the capping layer directly influencing out-coupling and optical fine-tuning of emission can easily be adjusted by means of the volume ratio of the two materials. It is of particular advantage to provide the second material in granular form, the granules being smaller than the wavelength of the light emitted by the optoelectronic member. The second material of the granules may be of a higher refractive index material comprising oxygen. Being in the solid state prior to and during deposition and being embedded in the first material, the second material does not react chemically. Therefore, the light emitting surface may comprise a low work function material without deteriorating.

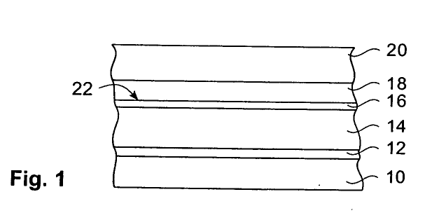

FIG. 1 is a schematic view of a vertical section through an optoelectronic device. The optoelectronic device comprises a TFT-layer 10 comprising thin film transistors (TFT) in a semiconductor layer. On the TFT-layer, an optoelectronic member comprising an anode 12, a light emitting material layer 14 and a cathode 16 is disposed. The upper surface of the cathode 16 is a light emitting surface 22 of the stack formed by the anode 12, the light emitting material layer 14 and the cathode 16. On top of the cathode 16, a capping layer 18 is provided. An encapsulating layer 20 is provided on top of the stack.

By application of a predetermined voltage between the cathode 16 and the anode 12, the light emitting material layer 14 is stimulated to emit light. The colour or the spectrum of the emitted light depends on the light emitting material, its optical thickness and the complex refractive indices of the electrodes 12, 16. In this embodiment, the light emitting material is an organic material with electroluminescent properties.

In the lateral directions, the anode 12 (and/or the cathode 16) is subdivided into a two-dimensional rectangular matrix of pixels. The voltage applied to the light emitting material layer 14 via the anode 12 and the cathode 16 is controlled individually for each pixel by electronic means incorporated into the TFT-layer 10.

The cathode 16 comprises a low work function material, for example Ca or Mg. Due to the low work function, a low voltage is sufficient to inject electrons from the cathode 16 into the light emitting material layer 14. The cathode layer 16 is rendered as thin as possible in order to be transparent for the light emitted from the light emitting material layer 14.

The capping layer 18 comprises a mixture of a first material having a first refractive index and a second material having a second refractive index. The mixture has an intermediate refractive index according to the volume ratio and the refractive indices of the first and second material. Thus, the refractive index of the mixture is tuneable and can be adjusted to the requirements of the application. In particular, the refractive index of the capping layer 18 is tuned such that losses through internal reflections are minimized by optical interference. This means that light from the light emitting material layer 14 is not reflected but completely transmitted through the capping layer 18. Taking into account the other layers, in particular the cathode 16 and the encapsulating layer 20, their refractive indices and thicknesses, an optimum refractive index of the capping layer 18 is typically in the range between about 2 and about 3.

The situation becomes even more complex if a display or display device comprises different light emitting materials emitting light with different wavelengths in adjacent pixels. The display or display device comprises usually multiple optoelectronic devices. In order to simplify the manufacturing of the display device, one laterally homogeneous capping layer 18 should be used. For a high outcoupling efficiency the refractive index of the capping layer 18 should be proportional to the wavelength. However, the majority of materials show normal dispersion, i.e. the refractive index decreases with increasing wavelengths. As will be clearer from the subsequent paragraphs, the present invention facilitates the provision of a capping layer with an abnormal dispersion.

The capping layer 18 can comprise a mixture of two or more materials with different optical properties each. Optimum or near optimum properties of the capping layer 18 are achieved by selecting appropriate volume ratios of the materials of the mixture. Further optical properties which are set via the volume ratio are spectral properties and the solid angle of emission.

In a simple example the mixture comprised in the capping layer 18 consists of two components. One component is, e.g., a polymer, a liquid crystal system or a wax or a composite of either. The second material is a high-refractive-index material, e.g. a titanium oxide, a zinc sulphide or any other oxide, sulphide or selenide of lead, zinc or titanium. The second material provides a refractive index with normal or abnormal dispersion. Additional degrees of freedom are introduced by further (third, fourth etc.) components with different normal or abnormal dispersions each.

Preferably one of the materials comprised in the mixture in the capping layer 18 is a liquid desiccant system. In this case, an improved out-coupling is combined with an enhanced stability. Further, preferably the second material is a high-refractive-index material and comprises or consists of nano-particles. In other words, the capping layer 18 comprises a mixture of a first material and granules from a second material. The granules are smaller or significantly smaller than the wavelengths of the light to be transmitted through the capping layer 18. With the granules or particles significantly smaller than the wavelength, scattering of light can be neglected. Therefore, the size of the granules is in the order of 100 nm or less.

Alternatively, light scattering from granules the size of which is comparable to the wavelength can be applied profitably. With appropriate size, shape and concentration of the granules, a type of photonic crystal structure in the capping layer 18 can be provided. A viewing angle characteristic of the display device can be tailored to the application of the device via diffraction occurring at two-dimensional or three-dimensional periodic arrangements of granules from the second material in the first material. The formation of such a lattice is controlled via the size, shape and concentration of the granules and other properties of both materials as well as via the conditions during generation of the capping layer 18.

A further improvement of the optical properties of the capping layer 18 can be achieved if the capping layer 18 consists of several layers wherein the optical properties of each layer are adjusted to optimum optical properties of the entire capping layer 18 with transparency, spectral properties and viewing angle tailored to the specific application of the device.

For the same reason or for similar results and improvements, the refractive index can be graded continuously within a one-layer capping layer 18 or within one layer of a multi-layer capping layer 18.

A mixture of a first material and granules from a second material provides further advantages. In particular, the probability or risk of a chemical reaction between the second material and the cathode 16 is lowered. This is because the second material is provided in the solid state and the granules from the second material are embedded in the first material. For both reasons, a chemical reaction between the second material and the cathode 16 does not take place or at least has a significantly lower rate. Therefore, the second material may for example even comprise oxygen, although the cathode is made from a low work function material, e.g. Ca or Mg, which is easily oxidized. To put it in other words, according to the present invention, the capping comprises a first component providing chemical and other properties facilitating the deposition of the capping layer 18 and a second or a third component or further components ensuring optimum optical properties.

The capping layer 18 is covered by an encapsulating layer 20, protecting the light emitting device from environmental influences such as humidity or reactive atmospheres. Alternatively, the encapsulating layer 20 further covers the edges or side faces of the capping layer 18, the cathode 16, the light emitting material layer 14, the anode 12 and/or the TFT-layer 10. The encapsulating layer 20 does not or not significantly influence the optical properties of the device. In particular, it is typically between 10 μm and 50 μm thick or thicker. Thus, no interference phenomena occur. Additionally, a gap may be provided between the capping layer 18 and the encapsulating layer 20. The optical effect of the gap is minimal if it is thick compared to the wavelength of the light to be transmitted. With the above-described display device, in particular with the above-described capping layer 18, an out-coupling of 50% and more can be achieved.

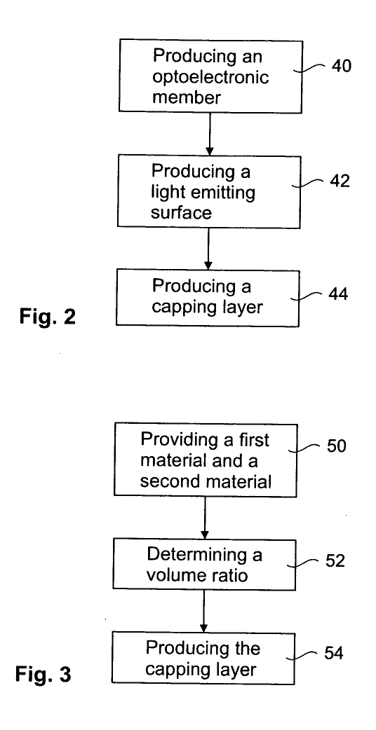

FIG. 2 is a schematic flow chart of a method for manufacturing an optoelectronic device as described above. In a first step 40, an optoelectronic member for generating photons of predefined wavelengths is produced. Referring to the embodiment shown in FIG. 1, this step comprises the deposition of the anode 12, the light emitting material layer 14 and the cathode 16 on the TFT-layer 10.

A second step 42 of producing a light emitting surface on the optoelectronic member is a separate step or, alternatively, conducted during the step 40 for producing the optoelectronic member. In particular, the light emitting surface is the cathode 16 or its surface 22.

Finally, in a third step 44, the capping layer 18 is produced on the light emitting surface 22. According to one embodiment, the materials are sprayed on the light emitting surface 22 in order to form the capping layer 18. The material may be sprayed together from one spray source, simultaneously, from different spray sources or alternatingly, wherein the mixture arises by diffusion, self-organisation or self assembly.

As an alternative, the materials or at least one of the materials of the capping layer 18 are deposited reactively in a chemical vapour deposition process or a similar process, wherein the first material (or the second material) is produced in a chemical reaction from a raw material during deposition of the raw material on the light emitting surface. Furthermore, the capping layer 18 may be produced by spin-coating or any other conventional method.

FIG. 3 is a schematic flow chart of a method for defining the refractive index of a capping layer 18 of an optoelectronic device. In a first step 50, a first material having a first refractive index and a second material having a second refractive index, are provided or selected or identified. In a second step 52, a volume ratio of the first material and the second material is determined such that a mixture of the first material and the second material with the determined volume ratio has a predetermined refractive index. In a third step 54, the capping layer is produced from a mixture of the first material and the second material at the determined volume ratio.

The present invention is not restricted to a device comprising the stack geometry shown in FIG. 1. Rather, it may be applied for any optoelectronic device with any geometry of the electrodes and the light-emitting material, for example for devices with a co-planar arrangement of the electrodes and the light-emitting material. Further, the capping layer may comprise a mixture of any number of materials. The more materials are comprised in the mixture, the better its optical properties can be adjusted to the needs of the application of the device. The advantage of granules have been described above and are valid for a multi-material mixture, as well.

Variations described for the present invention can be realized in any combination desirable for each particular application. Thus particular limitations, and/or embodiment enhancements described herein, which may have particular advantages to the particular application need not be used for all applications. Also, not all limitations need be implemented in methods, systems and/or apparatus including one or more concepts of the present invention.

It is noted that the foregoing has outlined some of the more pertinent aspects and embodiments of the present invention. This invention may be used for many applications. Thus, although the description is made for particular arrangements and methods, the intent and concept of the invention is suitable and applicable to other arrangements and applications. It will be clear to those skilled in the art that modifications to the disclosed embodiments can be effected without departing from the spirit and scope of the invention. The described embodiments ought to be construed to be merely illustrative of some of the more prominent features and applications of the invention. Other beneficial results can be realized by applying the disclosed invention in a different manner or modifying the invention in ways known to those familiar with the art.

What is claimed, as:

1. An optoelectronic device comprising:
an optoelectronic member for emitting light;
a light emitting surface; and
a capping layer on the light emitting surface, wherein the capping layer comprises a mixture of a first material having a first refractive index and a second material having a second refractive index.

2. The optoelectronic device according to claim 1, wherein the mixture comprises granules of the second material.

3. The optoelectronic device according to claim 2, wherein the granules of the second material are smaller than the wave-length of light which is emittable by the optoelectronic member.

4. The optoelectronic device according to claim 1, wherein the second refractive index is higher than the first refractive index.

5. The optoelectronic device according to claim 1, wherein the first material comprises one of: a desiccant, a polymer, a liquid crystal system, and a wax.

6. The optoelectronic device according to claim 1, wherein the second material having a refractive index showing abnormal dispersion.

7. The optoelectronic device according to claim 1, wherein the second material is one of: an oxide, sulphide of lead, selenide of lead, zinc, and titanium.

8. The optoelectronic device according to claim 1, wherein the capping layer further comprises granules of a third material having a third refractive index.

9. The optoelectronic device according to claim 1, wherein the mixture and the refractive index of the mixture vary within the capping layer.

10. The optoelectronic device according to claim 2, wherein the granules of the second or third material are nano-particles.

11. The optoelectronic device according to claim 1, wherein the light emitting surface is a surface of an cathode, the cathode comprising a low work function material and the second material being an oxide.

12. The optoelectronic device according to claim 1, wherein the capping layer is covered by a transparent material.

13. The optoelectronic device according to claim 1, forming a display device.

14. A capping layer disposed on an electrode, said capping layer comprising:
a mixture of
a first material having a first refractive index, and
a second material having a second refractive index.

15. A method for manufacturing an optoelectronic device, comprising:
producing an optoelectronic member for generating photons of a predefined wavelength;
producing a light emitting surface on the optoelectronic member; and
producing a capping layer on the light emitting surface,
wherein the capping layer comprises a mixture of a first material having a first refractive index and a second material having a second refractive index.

16. The method according to claim 15, wherein the step of producing the capping layer comprises a step of spraying the mixture onto the light emitting surface.

17. The method according to claim 15, wherein the first material is produced in a chemical reaction from a raw material during deposition of the raw material on the light emitting surface.

18. A method for defining a refractive index of a capping layer of an optoelectronic device, comprising:
providing a first material having a first refractive index and a second material having a second refractive index;
determining a volume ratio of the first material and the second material such that a mixture of the first material and the second material with the determined volume ratio having a predetermined refractive index; and
producing the capping layer from the mixture of the first material and the second material at the determined volume ratio.

19. The optoelectronic device according to claim 8, wherein the granules of the second or third material are nano-particles.

20. The optoelectronic device according to claim 1, wherein:
the mixture comprises granules of the second material;
the granules of the second material are smaller than the wavelength of light which is emittable by the optoelectronic member;
the second refractive index is higher than the first refractive index;
the first material comprises one of: a desiccant, a polymer, a liquid crystal system, and a wax; and
the second material having a refractive index showing abnormal dispersion.
